(19) United States
(12) Patent Application Publication
(10) Pub. No.: US 2008/0048695 A1
(43) Pub. Date: Feb. 28, 2008

(54) CIRCUIT SUBSTRATE, METHOD FOR INSPECTING ELECTRIC CIRCUIT, AND METHOD FOR MANUFACTURING CIRCUIT SUBSTRATE

(76) Inventor: Nobuyuki ASHIDA, Nara (JP)

Correspondence Address: NIXON & VANDERHYE, PC, 901 NORTH GLEBE ROAD, 11TH FLOOR, ARLINGTON, VA, 22203, US

(21) Appl. No.: 11/842,445

(22) Filed: Aug. 21, 2007

(30) Foreign Application Priority Data
Aug. 25, 2006 (JP) 2006-229587

(51) Int. Cl. G01R 31/02; H01R 12/04

(52) U.S. Cl. 324/755; 174/261

(57) ABSTRACT

According to an embodiment of a circuit substrate of the present invention, in a circuit substrate provided with a plurality of circuit blocks formed on a single substrate, at least one of the metal patterns connecting the circuit blocks is separated into two sections at some midpoint of wiring, and exposed conductor portions whose end portions are to be bridge-connected through soldering are provided at the end portions in the separated portion of the separated two wiring metal patterns.

### BACKGROUND OF THE INVENTION

This application claims priority under 35 U.S.C. §119(a) on Patent Application No. 2006-229587 filed in Japan on Aug. 25, 2006, the entire contents of which are hereby incorporated by reference.

### FIELD OF THE INVENTION

The present invention relates to a circuit substrate on which a plurality of circuit blocks are connected to one another through a wiring metal pattern, a method for testing an electric circuit that is formed by mounting an electronic component on the circuit substrate, and a method for manufacturing a circuit substrate.

### DESCRIPTION OF THE RELATED ART

In recent years, as multifunctionality and size reduction have been sought in electronic devices, formation of a plurality of electric circuits each having a different function on a single circuit substrate has been sought.

For example, in a conventional analog television broadcast receiving apparatus, only an intermediate frequency transformer circuit that transforms high-frequency signals received through an antenna into intermediate frequency is formed on a single circuit substrate. In a digital television broad cast receiving apparatus, in addition to an intermediate frequency transformer circuit, as a circuit provided subsequent to the intermediate frequency transformer circuit, formation of a digital demodulator circuit that demodulates digitally modulated signals to transport streams; a video/audio processing circuit for extracting video signals and audio signals from compressed digital signals; or the like on a single circuit substrate has been sought,

Meanwhile, in a circuit substrate on which a plurality of electric circuits is provided, it is desirable to be able to perform a test with the electric circuits of different functions electrically separated from one another.

Accordingly, as a testing method with the electric circuits electrically separated from one another, in JP 2005-129790A (hereinafter referred to as “Patent Document 1”), a method using a circuit substrate that is structured by forming an exposed testing signal conductor portion at the end portion of a signal line metal pattern of circuit block and by forming an exposed testing ground conductor portion placed near the exposed testing signal conductor portion has been proposed.

Hereinafter, the method proposed in Patent Document 1 will be described.

FIG. 6 is an enlarged view of a conventional circuit substrate that shows an enlarged end portion of a signal line metal pattern of each circuit block.

A circuit substrate 100 is provided with a circuit block AA and a circuit block BB. The circuit block M and the circuit block BB are electrically separated by a slit 117 of a predetermined width. Signal line metal patterns 115 connecting the circuit block AA and the circuit block BB are separated by the slit 117, and land patterns 230 are provided on the separated portion so as to achieve an electrical connection by mounting a surface-mounted component 200. In addition, an exposed testing conductor portion 240 is provided in the separated portion of the respective signal line metal patterns 115 so as to allow contact of a terminal of a testing tester. Furthermore, exposed testing ground conductor portions 250 are provided on both sides of each of the signal line metal patterns 115.

Electrical properties of a mounted circuit substrate that is formed by mounting electronic components to the circuit substrate 100 are tested as follows. Each of the electric circuits is tested by mounting electronic components other than the surface-mounted component 200, which is to be mounted to the separated signal line metal patterns 115, and by placing a testing probe in contact with the exposed testing conductor portion 240 as well as with the exposed testing ground conductor portions 250. Such a method allows a test to be performed with each of the electric circuits electrically separated.

After performing a test on each of the electric circuits, surface components 200 such as a jumper resistor and a capacitor for alternate current coupling are mounted so as to bridge the two land patterns 230, thus electrically connecting the electric circuits to complete the entire circuit.

The technology described in Patent Document 1, however, has the problem that completion of a circuit is labor intensive because a surface component needs to be mounted to connect the electric circuits after completion of the testing.

### SUMMARY OF THE INVENTION

The present invention was made in view of the above-described problems, and it is an object thereof to provide a circuit substrate in which separated portions of wiring metal patterns connecting electrical blocks can be connected with simple work; a method for testing electric circuits formed by mounting electronic components on the circuit substrate; and a method for manufacturing a circuit substrate.

A circuit substrate according to the present invention is a circuit substrate having a plurality of circuit blocks formed on a single substrate, in which at least one of the wiring metal patterns connecting the circuit blocks to one another is separated into two sections at some midpoint of wiring, and in which an exposed conductor portion is provided at the end portion of the separated portion of the separated two wiring metal patterns, the end portion to be bridge-connected to each other through soldering.

With a circuit substrate according to the present invention, a wiring metal pattern that connects circuit blocks to each other is separated, and both of the end portions of the wiring metal pattern in the separated portion are used as the exposed conductor portions to be bridge-connected through soldering, thus allowing connection of the separated wiring metal patterns through soldering. Thus, a step of connecting the circuit blocks is simplified. As a result, the time and cost required for manufacturing a circuit substrate can be reduced,

In addition, in a configuration in which a wiring metal pattern that connects each of the circuit blocks is separated, the location of separation is not limited; the wiring metal pattern can be separated at any location. Thus, the degree of freedom is not impaired when designing circuits of each of the circuit blocks and when designing layout of the circuit blocks.

In addition, in a circuit substrate according to the present invention, a solder layer may be formed on the exposed conductor portions.

In this configuration, the separated portion of the wiring metal patterns can be easily connected by soldering.

Furthermore, in a circuit substrate according to the present invention, both of or one of the exposed conductor portions may have a shape with which a probe pin of a testing tester can come in contact.

In this configuration, the exposed conductor portions of the wiring metal patterns may be used as a testing pad for testing electric circuits (electric circuits formed by mounting the predetermined electronic components on circuit blocks), and there is no need to newly provide a testing pad.

In addition, a method for testing an electric circuit according to the present invention is a method for testing electrical properties of each of the electric circuits that have been formed by mounting the predetermined electronic components onto each of a circuit block on any of circuit substrates according to the present invention, in which testing of the electrical properties of each of the electric circuits is performed prior to electrically connecting each of the electric circuits to one another.

According to this testing method, each of the electric circuits (electric circuits formed by mounting the predetermined electronic components on circuit blocks) can be tested in a state in which the wiring metal patterns that connect each of the circuit blocks are separated. In other words, electrical properties of each of the electric circuits can be tested while electrical effects from the other electric circuits are eliminated.

Furthermore, in a method for testing an electric circuit according to the present invention, testing of the electrical properties may be performed concurrently on a plurality of circuit blocks.

In this configuration, the time required for testing the entire circuit can be reduced since electrical testing is concurrently performed on each electric circuit.

Furthermore, in a method for manufacturing a circuit substrate according to the present invention, electrical properties are tested in any of the above-mentioned methods on each of electric circuits that have been formed by mounting the predetermined electronic components onto each of the circuit blocks on any one of the circuit substrates, the exposed conductor portions are bridge-connected to each other subsequent to the testing, and each of the electric circuits is electrically connected to one another.

According to this manufacturing method, the functions and effects similar to the above can be obtained, and highly reliable circuit substrates can be efficiently provided since a circuit substrate according to the present invention is used, and each of the electric circuits, which has been tested in advance with a testing method according to the present invention, is electrically connected to one another by bridge-connecting the exposed conductor portions through soldering.

### BRIEF DESCRIPTION OF THE DRAWINGS

FIG. 1 is a schematic view of a circuit substrate according to this embodiment.

FIG. 2 is an enlarged view of a circuit substrate according to this embodiment showing a separated portion that separates a wiring metal pattern.

FIG. 3 is an explanatory drawing of a circuit substrate according to this embodiment that illustrates a separated portion of a wiring metal pattern.

FIG. 4 is a cross-sectional view of a circuit substrate according to this embodiment that illustrates a separated portion of a wiring metal pattern.

FIG. 5 is an explanatory drawing of a circuit substrate according to this embodiment that illustrates a state in which a separated portion of a wiring metal pattern has been connected.

FIG. 6 is an enlarged view of a conventional circuit substrate that shows an enlarged end portion of a signal line metal pattern of each of electric circuit patterns.

### DESCRIPTION OF THE PREFERRED EMBODIMENTS

Hereinafter, an embodiment of the present invention will be described with reference to the drawings.

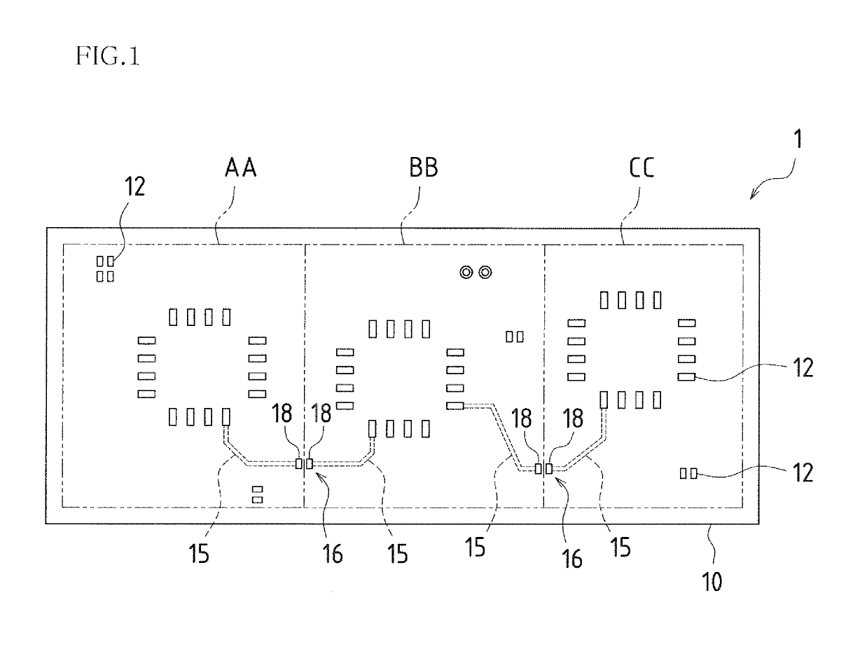

FIG. 1 is a schematic view of a circuit substrate according to this embodiment.

A circuit substrate i according to an embodiment of the present invention is for forming a plurality of electric circuits that each have a different function on a single substrate 10.

For example, a circuit substrate like the circuit substrate 1 is used for formation of a circuit of a digital television broadcast receiving apparatus.

More specifically, a digital television broadcast receiving apparatus is configured from a plurality of electric circuits, such as an intermediate frequency transformer circuit that transforms high-frequency signals received from an antenna into intermediate frequency; a digital demodulator circuit that demodulates signals output from a transformer circuit to transport streams; and a video/audio processing circuit for extracting video signals and audio signals from compressed digital signals; and the circuit substrate 1 according to this embodiment is used in order to realize a circuit configured from these electric circuits on a single substrate.

Circuit blocks AA, BB, and CC are formed on the circuit substrate I so as to correspond to the respective electric circuits, and the circuit blocks AA, SB, and CC are connected to each other with a wiring metal pattern 15.

The circuit blocks AA, BB, and CC are configured from land patterns 12, a wiring pattern (not shown) for connecting the land patterns 12, and others. The wiring pattern is covered with a solder resist and thus protected.

Among the several wiring metal patterns 15 that connect the circuit blocks AA, BB, and CC to one another, a predetermined wiring metal pattern is separated at some midpoint of wiring so as to form two wiring metal patterns 15.

In determining the wiring metal pattern 1.5 to be separated, the wiring metal pattern 15, if it exists, from which electrical effects from other electric circuits arise during the test of electrical properties of the predetermined electric circuits (electric circuits formed by mounting predetermined electronic components on the circuit blocks AA, BB, and CC), is selected. Such a configuration can eliminate effects from other electric circuits or suppress such effects to a low level during testing of the predetermined electric circuits for their electrical properties.

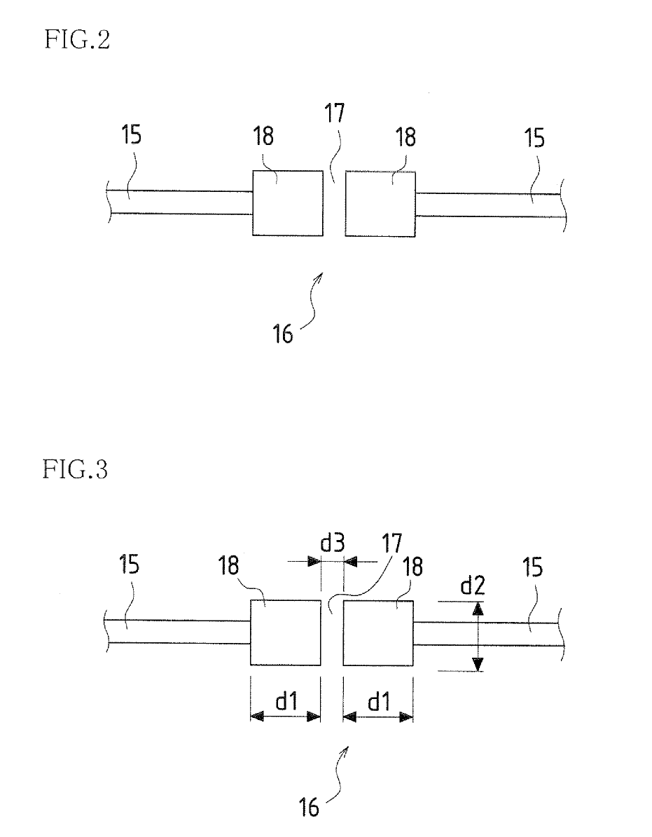

FIG. 2 is an enlarged view of a circuit substrate according to this embodiment showing a separated portion that separates a wiring metal pattern. FIG. 3 is an explanatory drawing of a circuit substrate according to this embodiment that illustrates a separated portion of a wiring metal pattern. FIG. 4 is a cross-sectional view of a circuit substrate according to this embodiment that illustrates a separated portion of a wiring metal pattern.

A separated portion 16 is separated with a slit 17 of a predetermined width, and the separated two wiring metal patterns 15 are provided with exposed conductor portions 18 that are to be bridge-connected through soldering formed at the end portion of the respective separated portions 16. The exposed conductor portions 18 are formed by exposing conductors 20, and the surrounding areas are covered with solder resists 13.

Such a configuration, in which the wiring metal patterns 15 that connect the circuit blocks AA, BB, and CC to one another are separated, and the separated portion 16 is provided with the exposed conductor portions 18 formed at both ends of the wiring metal patterns 15, can simplify the work of connecting the circuit blocks by allowing bridging of the separated wiring metal patterns 15 through soldering. As a result, the time and cost required for manufacturing a circuit substrate can be reduced.

In addition, in a configuration in which the wiring metal patterns 15 that connect the circuit blocks AA, BB, and CC are separated, the location of separation is not limited and separation can be made at any location. Thus, the degree of freedom is not impaired in designing circuits of the circuit blocks AA, BB, and CC and in designing layout of the circuit blocks AA, BB, and CC.

In addition, both of the exposed conductor portions 18 are separated by a distance that can be bridged by applying a solder coating to both of the portions. This makes it possible to easily connect the separated portion 16 of the wiring metal patterns 15. Furthermore, the size of both of the exposed conductor portions 18 is designed so that the connection portion formed by connecting both of the exposed conductor portions 18 through soldering has sufficient strength.

For example, the exposed conductor portion 18 has a rectangular shape with a length d1 of 1.4 mm and a width d2 of 1.5 mm, and a slit width d3 between the exposed conductor portions 18 and 18 is 0.2 mm. The size of the exposed conductor portion 18 is not limited to this size, and is adjusted according to the surrounding wiring patterns or component layout.

In addition, both of or either of the exposed conductor portions 18 and 18 may have a shape with which a probe pin of a testing tester can come in contact. This configuration makes it possible to use the exposed conductor portions 18 of the wiring metal patterns 15 as testing pads for testing an electric circuit that has been formed by mounting the predetermined electronic components onto the circuit blocks AA, BB, and CC. In this case, since there is no need to newly provide a testing pad, the size of the circuit substrate 1 can be reduced by its size.

Furthermore, it is preferable to form solder layers 21 on the surface of the exposed conductor portions 18. The solder layers 21 are formed, for example, through solder printing or solder plating. This makes it possible to easily connect the separated portion 16 of the wiring metal patterns 15 through soldering.

Furthermore, it is preferable to form the solder layers of the exposed conductor portions 18 simultaneously with the task of forming the solder layers 21 to the land patterns 12 in a solder printing process of the circuit substrate 1. This can save labor of forming the solder layers 21 to the exposed conductor portions 18 in a newly provided separate process.

Hereinafter, a method for testing the circuit substrate I with electronic components mounted thereon will be described.

First, the predetermined electronic components are mounted onto each of the circuit blocks AA, BB, and CC, and each of the electric circuits is formed through reflow soldering to the circuit substrate 1. In this reflow process, the wiring metal patterns 15 that have been separated into two are not connected.

Testing of electrical properties is performed on each of the electric circuits in a state prior to connecting the separated portion 16 of the wiring metal patterns 15. In other words, electrical properties of each of the electric circuits can be tested with the electrical effects from the other electrical circuits eliminated since each of the electric circuits can be tested in a state in which the wiring metal patterns 15 that connect the circuit patterns AA, BB, and CC have been separated.

The testing of electrical properties may also be performed concurrently instead of separately on each of the electric circuits. This can reduce the testing time for the entire circuit.

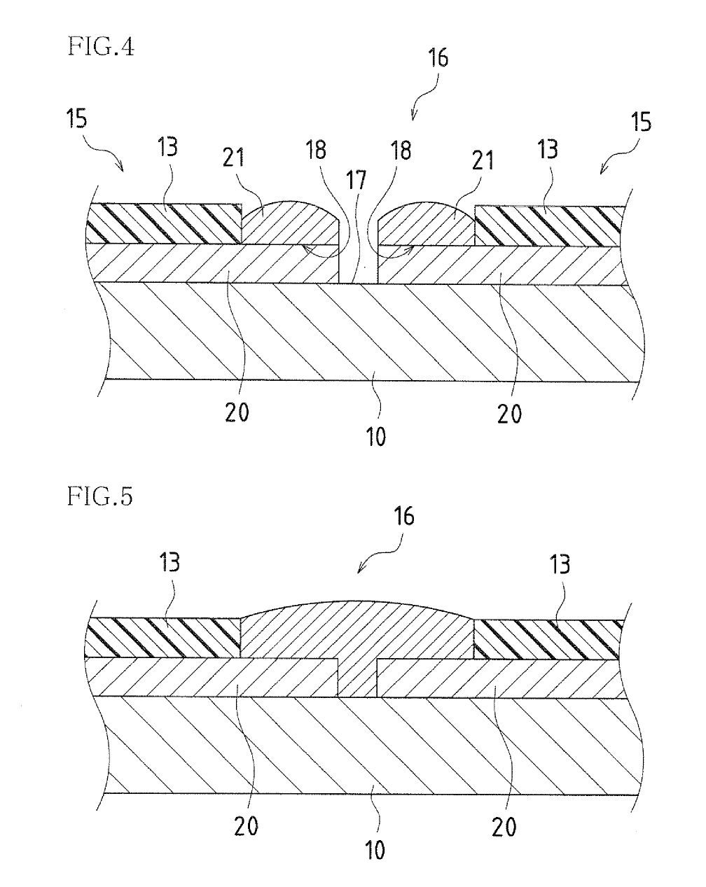

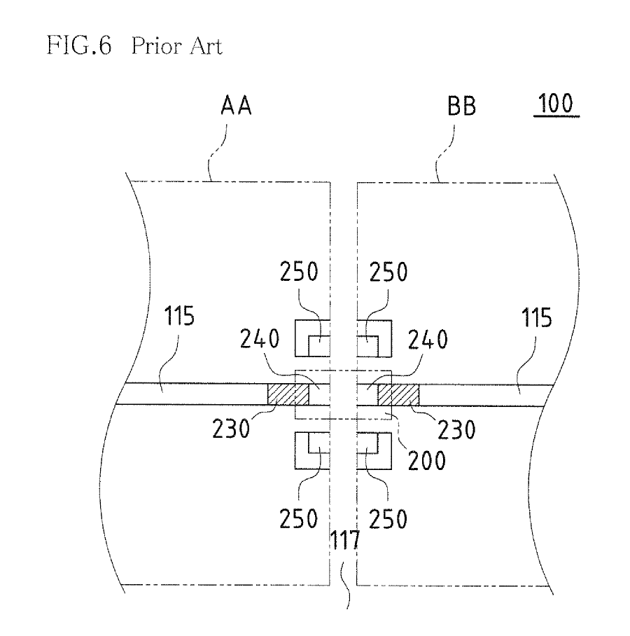

FIG. 5 is an explanatory drawing of a circuit substrate according to this embodiment that illustrates a state in which a separated portion of a wiring metal pattern has been connected.

Subsequent to the testing of electrical properties of each of the electric circuits, the separated portion 16 of the wiring metal patterns 15 is connected by soldering the separated portion 16. This electrically connects the electric circuits and completes the circuit.

The present invention may be embodied in various other forms without departing from the spirit or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

1. A circuit substrate in which a plurality of circuit blocks are formed on a single substrate,
wherein at least one wiring metal pattern connecting the circuit blocks to one another is separated into two sections at some midpoint of wiring; and
wherein an exposed conductor portion is provided at end portions in a separated portion of the separated two wiring metal patterns, the end portions to be bridge-connected to each other through soldering.

2. The circuit substrate according to claim 1, wherein a solder layer is formed on the exposed conductor portion.

3. The circuit substrate according to claim 1, wherein both or one of the exposed conductor portions have a shape with which a probe pin of a testing tester can come in contact.

4. A method for testing electrical properties of each of electric circuits that have been formed by mounting a predetermined electronic component onto each of the circuit blocks on the circuit substrate according claim 1,
wherein testing of the electrical properties of each of the electric circuits is performed prior to electrically connecting the electric circuits to one another.

5. The method for testing an electric circuit according to claim 4, wherein testing of the electrical properties is performed concurrently on the plurality of electric circuits.

6. A method for manufacturing a circuit substrate comprising the steps of:
performing testing the electrical properties by a method according to claim 4 o# on each of the electric circuits that have been formed by mounting a predetermined electronic component onto each of the circuit blocks on the circuit substrate; and
electrically connecting the electric circuits to one another by bridge-connecting the exposed conductor portions to each other subsequent to the testing.
